(19) United States
(12) Patent Application Publication
(10) Pub. No.: US 2007/0045756 A1
(43) Pub. Date: Mar. 1, 2007

(54) Nanoelectronic sensor with integral suspended micro-heater

(76) Inventors: Ying-Lan Chang, Cupertino, CA (US); Jean-Christophe P. Gabriel, Pinole, CA (US); Sergei Skarupo, Berkeley, CA (US); Alexander Star, Pittsburgh, PA (US); Christian Valcke, Orinda, CA (US); Qian Wang, Mountain View, CA (US)

Correspondence Address: O'MELVENY & MYERS LLP, 610 NEWPORT CENTER DRIVE, 17TH FLOOR, NEWPORT BEACH, CA, 92660, US

(21) Appl. No.: 11/488,465

(22) Filed: Jul. 18, 2006

Related U.S. Application Data
(63) Continuation-in-part of application No. 10/655,529, filed on Sep. 4, 2003, now abandoned.
(63) Continuation-in-part of application No. 10/280,265, filed on Oct. 26, 2002, now Pat. No. 6,894,359.
(60) Provisional application No. 60/408,362, filed on Sep. 4, 2002.
(60) Provisional application No. 60/408,412, filed on Sep. 4, 2002.
(60) Provisional application No. 60/700,953, filed on Jul. 19, 2005.

(51) Int. Cl. H01L 29/82

(52) U.S. Cl. 257/414

(57) ABSTRACT

A nanoelectronic sensing device includes a substrate, a nanostructure element disposed adjacent the substrate, and at least a conductive element electrically connected to the nanostructure element. The device is configured to heat at least a portion of the sensor structure including the nanostructure element. In certain embodiments, the nanostructure element comprises at least one nanotube, the nanotube being electrically connected to at least two conductors so as to permit an electric current on the order of 10 microAmps or greater to be passed through the nanotube, causing the nanotube to heat up relative to the substrate. In alternative embodiments, the sensing device includes a platform or membrane which is at least partially thermally isolated by one or more cavities, the platform supporting at least the nanostructure element adjacent to a microheater element. The heating of the sensor structure may be employed, for example, for thermoregulation, to accelerate and/or increase sensor response, and to improve other sensor characteristics.

### CROSS-REFERENCE TO RELATED APPLICATIONS

This application is a continuation-in-part of and claims priority to U.S. patent application Ser. No. 10/655,529 filed Sep. 4, 2003 entitled “Improved Sensor Device With Heated Nanostructure”, which claims priority to U.S. Provisional Application No. 60/408,362 filed Sep. 4, 2002;

This application is a continuation-in-part of and claims priority to U.S. patent application Ser. No. 10/280,265 filed Oct. 26, 2002 entitled “Sensitivity Control For Nanotube Sensors” (now U.S. Pat. No. 6,894,359), which claims priority to U.S. Provisional Application No. 60/408,412 filed Sep. 4, 2002;

This application claims priority to US Provisional Application No. 60/700,953 filed Jul. 19, 2005 entitled “Improved Sensor Device With Heated Nanostructure, Including Sensor Having Thermally Isolated Nanostructure Element And Integrated Micro-Heater”.

Each of the above identified patent applications are specifically incorporated herein, in their entirety, by this reference.

### BACKGROUND OF THE INVENTION

1. Field of the Invention

The present invention relates to sensors and other devices made from nanostructures, such as nanotubes.

2. Description of Related Art

Nanotube transistors and resistors can be made on silicon substrates. These devices are made by growing nanotubes by chemical vapor deposition directly on the substrates, although they can also be made by other methods known in the art, such as by growing nanotubes by laser ablation or chemical vapor deposition elsewhere and then placing then on the substrates. Subsequently, electrodes, such as metal wires, are patterned onto the substrate to connect the nanotubes into circuits.

Nanotube devices may be used as chemical sensors. For such applications, a passivation material to cover only the metal contacts, leaving a segment of nanotubes exposed. Alternatively, the passivation can cover the nanotubes entirely.

Such devices have been shown to respond to hydrogen, among other things. Such response may deteriorate with time. It is desirable, however, to restore and/or to increase the senitivity and responsiveness of nanotube devices to hydrogen and to other materials.

### SUMMARY OF THE INVENTION

The present invention provides a nanoelectronic sensing device includes a substrate, a nanostructure element disposed adjacent the substrate, and at least a conductive element electrically connected to the nanostructure element. The device is configured permit heating at least a portion of the sensor structure including the nanostructure element.

In certain embodiments, the nanostructure element comprises at least one nanotube or other conductive or semiconductive nanoelement, the nanotube being electrically connected to at least two conductors so as to permit an electric current on the order of 10 microAmps or greater to be passed through the nanotube, causing the nanotube to heat up relative to the substrate.

Note that the nanostructure element may comprise one or more nanostructures which can conduct current to heat Ohmically (examples include SWCNT, MWCNT, conductive nanowire, doped semiconductive nanowire, or the like). Alternatively, the nanostructure element may comprise a plurality of nanostructures in a network or assemblage in which some of the nanostructures are connected and configured to conduct and heat Ohmically, and in which the heating nanostructure(s) in turn warm adjacent nanostructure(s) which are not conducting significant current (either due to intrinsic properties or due to lack of a conductive path connection).

Such a nanotube device has demonstrated improved responsiveness to hydrogen and other materials. Surprisingly, it was found that the responsiveness of a nanotube sensor may be greatly enhanced by heating the nanotube independently of the substrate to which it is attached. This may be accomplished, for example, by ohmic heating. The device substrate may have a temperature substantially less than the heated nanostructure element (e.g., carbon nanotubes). For example, the base substrate may have a bulk temperature of less than about 100° C., where the operating temperature of the nanostructures (e.g., nanotube or nanotubes) attached to the substrate have a temperature substantially greater than 100° C., such as, for example, about 300° C. When operated in this condition, a nanotube sensor exhibits a much faster response to sensor targets such as hydrogen.

In alternative embodiments, the sensing device includes a platform or membrane which is at least partially thermally isolated by one or more cavities, the platform supporting at least the nanostructure element adjacent to a microheater element. The heating of the sensor structure may be employed, for example, for thermoregulation, to accelerate and/or increase sensor response, and to improve other sensor characteristics.

An embodiment of a transistor device having aspects of the invention comprises: (a) a microhotplate including a substrate having a bulk portion and a suspended portion, the suspended portion connected to the bulk portion so as to be substantially thermally isolated from the bulk portion; and at least one heating element disposed adjacent the suspended portion; and (b) a transistor including a semiconducting channel comprising one or more nanostructure elements, the channel disposed adjacent the suspended portion and configured so as to be heated by the heating element; at least a pair of contacts electrically communicating with the channel; at least one gate electrode configured to electrically influence the channel. The nanostructure elements comprise one or more carbon nanotubes, and the device may further comprising a temperature sensor. In an alternative, the device comprises a controller configured to control the heat produced by the heating element; receive a temperature signal from the temperature sensor; and regulate the heat produced by the heating element to maintain a target temperature of the channel. The transistor device may be configured as a sensor, e.g. including a recognition material.

An embodiment of sensor device having aspects of the invention for sensing at least an analyte of interest comprises: (a) a microhotplate including a substrate having a bulk portion and a suspended portion, the suspended portion connected to the bulk portion so as to be substantially thermally isolated from the bulk portion; and at least one heating element disposed adjacent the suspended portion; and (b) a nanosensor including at least one nanostructure element disposed adjacent the suspended portion and configured so as to be heated by the heating element; one or more contacts configured to electrically communicate with the nanostructure element; and a recognition material disposed in operative association with the nanostructure element and configured to interact with the analyte of interest. The nanostructure element may comprise one or more carbon nanotubes.

An embodiment of sensor device having aspects of the invention for sensing at least an analyte of interest comprises: a substrate; at least one elongate nanostructure element having a conductivity and disposed adjacent the substrate, wherein at least a portion of the elongate nanostructure element is space apart from the substrate; one or more conductive elements electrically connected to the nanostructure element and configured to permit an electrical current to be conducted along the elongate nanostructure element so as to dissipate energy as heat in at least a portion of the elongate nanostructure element; and a recognition material disposed in operative association with the nanostructure element and configured to interact with the analyte of interest. The sensor device may further comprising a gate electrode disposed to electrically influence the elongate nanostructure element. In one alternative, the substrate has a top surface and a slot in the top surface; the conductive elements comprise a pair of contacts adjacent the top surface on opposing sides of the slot; and the elongate nanostructure element is arranged to span the slot and to be in electrical communication with each of the pair of contacts.

An embodiment of a transistor device having aspects of the invention comprises: a substrate; at least one elongate nanostructure element having a conductivity and disposed adjacent the substrate, wherein at least a portion of the elongate nanostructure element is space apart from the substrate; one or more conductive elements electrically connected to the nanostructure element and configured to permit an electrical current to be conducted along the elongate nanostructure element so as to dissipate energy as heat in at least a portion of the elongate nanostructure element; and a gate electrode disposed to electrically influence the elongate nanostructure element. In one alternative, the substrate has a top surface and a slot in the top surface; wherein the conductive elements comprise a pair of contacts adjacent the top surface on opposing sides of the slot; and wherein the elongate nanostructure element is arranged to span the slot and to be in electrical communication with each of the pair of contacts. The slot may have a bottom surface disposed spaced-apart from the elongate nanostructure element, and wherein the gate electrode is disposed adjacent the bottom surface. The elongate nanostructure element comprises one or more carbon nanotubes.

A more complete understanding of the nanotube device will be afforded to those skilled in the art, as well as a realization of additional advantages and objects thereof, by a consideration of the following detailed description of the preferred embodiments. Reference will be made to the appended sheet of drawings which will first be described briefly.

### BRIEF DESCRIPTION OF THE DRAWINGS

FIG. 1A is a diagram showing an exemplary nanostructure sensing device according to the invention.

FIG. 1B shows an alternative exemplary nanostructure sensing device according to the invention having a suspended nanostructure, such as a carbon nanotube.

FIGS. 2A and 2B show response of a tin oxide functionalized nanotube sensor to three short exposures to hydrogen at 200° C. on a hot plate (a) at low current and (b) at high current.

FIGS. 3A and 3B show response of the Pd-decorated nanotube sensor to short exposures to hydrogen (a) after production and (b) after several days at ambient conditions.

FIGS. 3C and 3D show regeneration of the Pd-decorated sensor by (c) heating to 100° C. on a hot plate and by (d) passing 4 mA current through the device at room temperature.

FIGS. 4.1-4.8 show cross-sections of an exemplary sensor device with integrated micro-hotplate and having aspects of the invention, shown at successive stages of one exemplary fabrication procedure.

FIG. 5A shows an alternative exemplary nanostructure sensing device according to the invention having a suspended carbon nanotube and a local gate electrode.

FIGS. 5B and 5C are SEM micrograph images of an embodiment generally similar to that diagramed in FIG. 5A

FIGS. 6.1-6.10 show cross-sections and plan view of an alternative exemplary sensor device with integrated micro-hotplate and having aspects of the invention, shown at successive stages of an alternative exemplary fabrication procedure.

### DETAILED DESCRIPTION OF THE PREFERRED EMBODIMENT

The present invention provides a method and structure for improving and/or restoring the response time of a nanostructure sensor device.

Nanostructure sensing devices can be heated by passing a current through the nanotubes, so-called ohmic heating. The benefit provided by this technique is that much less power is required to maintain a section of nanotube at hundreds of degrees Celsius than any macroscopic heating method. To see why, consider the thermal conductance between the nanotube and the substrate.

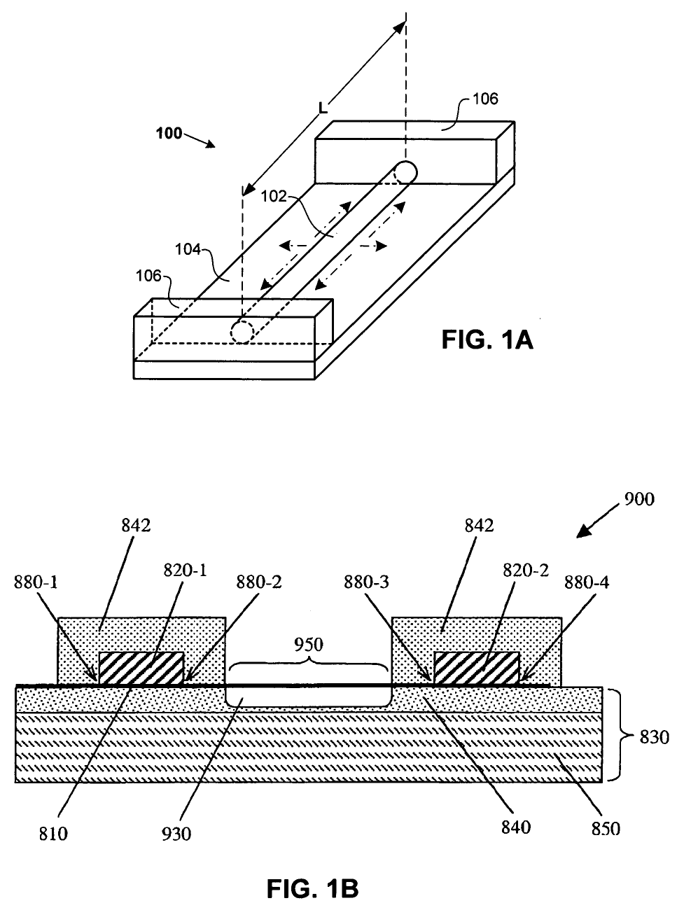

FIG. 1 shows an exemplary nanostructure sensing device 100, using a single nanotube, preferably a single wall carbon nanotube (SWNT). Device 100 comprises a nanotube 102, such as a carbon nanotube, disposed over a substrate 104, such as a silicon or other semiconductor substrate, or a non-conducting substrate. At least two conductive elements 106 are disposed over the substrate, and electrically connected to the nanotube. devices which use a plurality of nanotubes may also be constructed.

Note that alternatively to a SWNT, a device having aspects of the invention may include other conducting or semiconducting nanostructures , such as multiwall nanotubes, nanowires, nanorods and the like. Likewise a device may include a plurality of such nanostructures connected in parallel.

The nanotube conducts along its length “L” with the thermal conductivity of graphite in-plane, 19.5 W/mK. For a nanotube of diameter “D” in nm and length L in μm, the resulting conductance is 2×10⁻¹¹W/K D²/L. With 1.4 nm nanotubes and typical exposed lengths of about 0.5 μm, this thermal conductance is 40 pW/K, a very small number (Measuring this thermal conductivity is an interesting and difficult experiment that has been attempted by Philip Kim, see P Kim, L Shi, A Majumdar, and P L McEuen, Phys Rev Lett (2001) 87, 21). It is negligible compared to the thermal conductance from the tube directly to the substrate.

We can estimate that the conductivity of the interface is not likely to be greater than the conductivity of graphite perpendicular to its sheets, 0.057 W/mK. Roughly speaking, the conductance of a nanotube of length “L” and diameter “D”, separated from the substrate by a thickness “t” in nm which is comparable to the graphite interlayer spacing, is 5.7×10⁻⁸W/K DL/t. For typical numbers of D=1.4, L=0.5, t=0.3, this conductance is about 10 nW/K. This is an upper bound, and the actual conductance may be much smaller. An additional contribution of similar magnitude comes from conduction through the layer of water which is likely to surround nanotubes in air.

While the thermal conductance to remove heat from the nanotube is quite low, a significant amount of energy can be deposited in a nanotube. Currents of 10 s of μA can be passed through a single tube with voltages of around a volt. The resulting power of 10 s of μW is not all deposited in the nanotube. A significant fraction of it is deposited directly in the contacts. Any defect or other source of resistance in the nanotube will dissipate some of this heat, however, and the nanotube may get quite hot.

FIG. 1B shows an alternative exemplary nanostructure sensing device according to the invention having a suspended nanostructure, such as a carbon nanotube. FIG. 1B is essentially identical to FIG. 9 of parent application and U.S. Pat. No. 6,894,359, which is incorporated by reference, and the description related to said FIG. 9 is to be noted.

Nanostuctured sensor device 900 is generally similar to FIG. 1A in overall layout. Device 900 has a nanostructure 810 disposed adjacent substrate 830. In one preferred embodiment nanostructured layer 810 may include a single walled carbon nanotube or a plurality of nanotubes, such as a network or parallel series of nanotubes. Device 900 includes a pair of contact or conducting elements 820 is in electrical communication with nanostructure 810 (contacts 820-1 and 820-2 are shown). In this example, passivation 842 covers both contacts 820 and the adjacent portion of nanostructure layer 810.

Substrate 830 includes at least a base layer 850 (e.g., doped silicon wafer), and a top portion 840 (e.g. a layer of SiO2, or alternatively a layer of Si3N4 covered in a surface layer of SiO2, or the like), which provides electrical isolation of the base layer 850 from contacts 820 and nanostructured layer 810. Device 900 includes a trench 930 in the top layer 840 of the substrate 830 below a section 950 of the nanostructure 810. The trench 930 isolates the section 950 of the nanostructure layer 810 from the substrate 830, permitting the nanostructure 810 to be heated by Ohmic resistance to current flowing between contacts 820-1 and 820-2, with nanostructure 810 substantially thermally isolated from substate 830.

The trench 930 can be formed by a variety of micromachining techniques known in the art, such as wet etching, by dry etching, or by any method that will remove substrate material 840, 830 without harming the nanostructure 810. Buffered oxide etch (BOE), which is well known in the semiconductor arts, can be used as a wet etch agent for silicon oxides. Dry etch gases such as xenon dilfluoride (XeF2) can be used to etch silicon. It can be seen that the dimensions of the various layers and elements of device 900 can be selected by one of ordinary skill in the art without undue experimentation to optimize device characteristics. In one embodiment, the depth of the trench is between about 1 nm and 1 mm. In another embodiment, the depth of the trench is between about 10 nm 100 nm.

It is understood that the nanostructure 810 (or other device elements such as 820 and 840) may include functionalization or recognition material (not shown) suited to sensitivity and/or selectivity for an analyte or analytes of interest. In addition, device 900 may include encapsulation and/or filters (not shown) on all or a portion of the exposed device surface to improve selectivity or aspects of sensor performance or life.

For operation as a transconductance sensor, a voltage may be applied between the pair of contacts (820-1 and 820-2 as shown) so that one contact acts as a source electrode and one contact acts as a drain electrode. The supply voltage may be dc, ac, or both.

For operation as a field effect transistor sensor (e.g., an NTnetworkFET) a voltage supply (not shown can apply a voltage to the base substrate 850 so that it can act as an undifferentiated gate electrode for the device 900. The gate voltage can be dc, ac, or both. Alternatively, other gate electrode types (not shown) may be included, such as a top gate, side gate, metal bottom gate, liquid media gate, and the like.

For operation as a capacitance or impedance sensor, the capacitance may be measured for the substrate 850 relative to nanostructure 810.

### Demonstration of Heating Effects

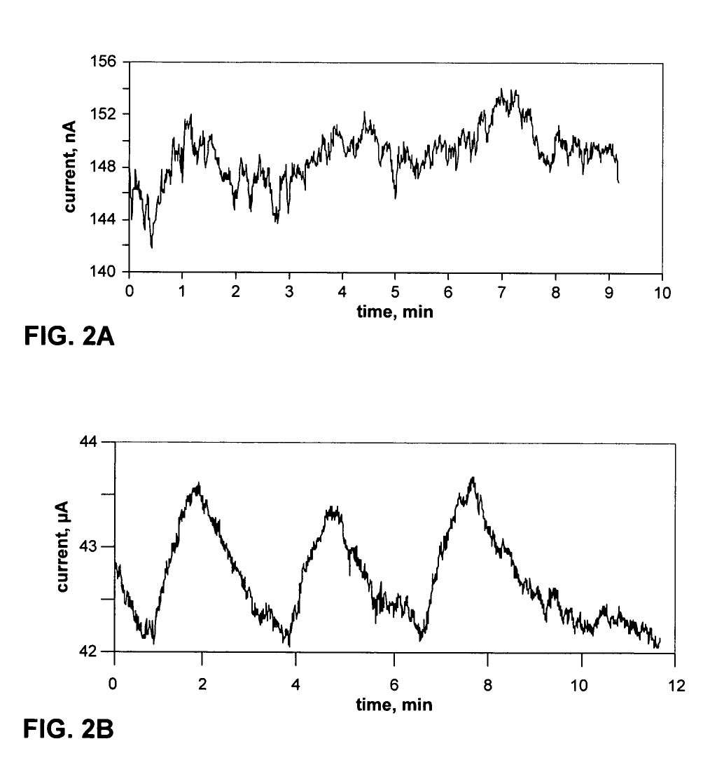

FIGS. 2-4 demonstrate heating effects with respect to a device such as is shown in FIG. 1A. Surprisingly, it may be used it to improve the response of a nanotube sensors. Two examples are demonstrated in FIGS. 2A-B and 3A-D.

FIGS. 2A-B show the effect of ohmic heating to heat a section of a nanotube to the temperature necessary for sensing action. Conventional tin oxide (SnO₂) sensors need to be heated to ˜300° C. for best operation. FIG. 2A shows the response of the SnO₂ functionalized nanotube chemical sensor at 200° C. and low current (˜140 nA). FIG. 2B shows the response of the same device high current (˜43,000 nA). Ohmic heating due to the high current has increased the temperature of at least a portion of the nanotube to a typical operating temperature of about 300° C.

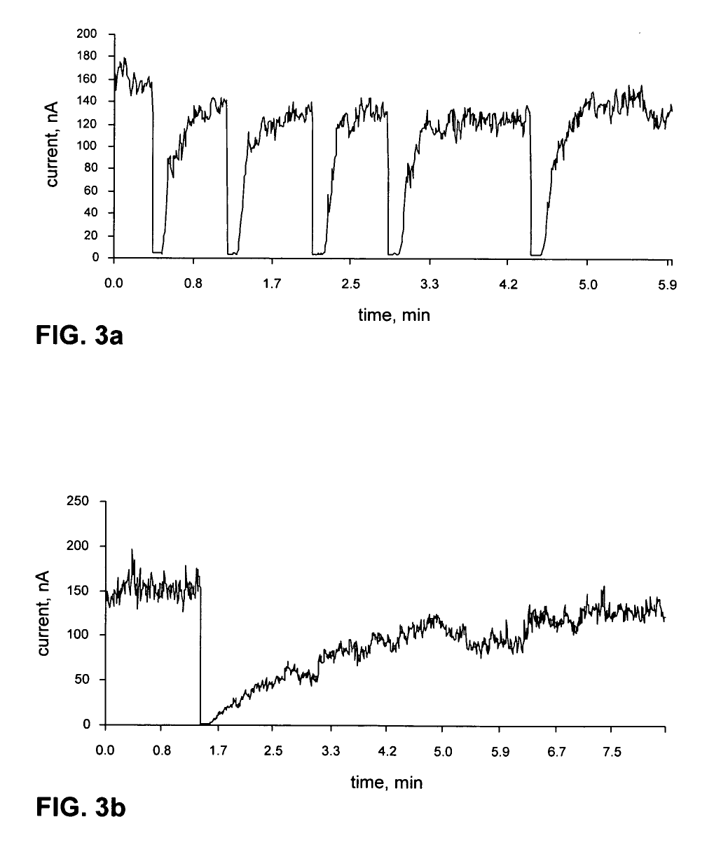

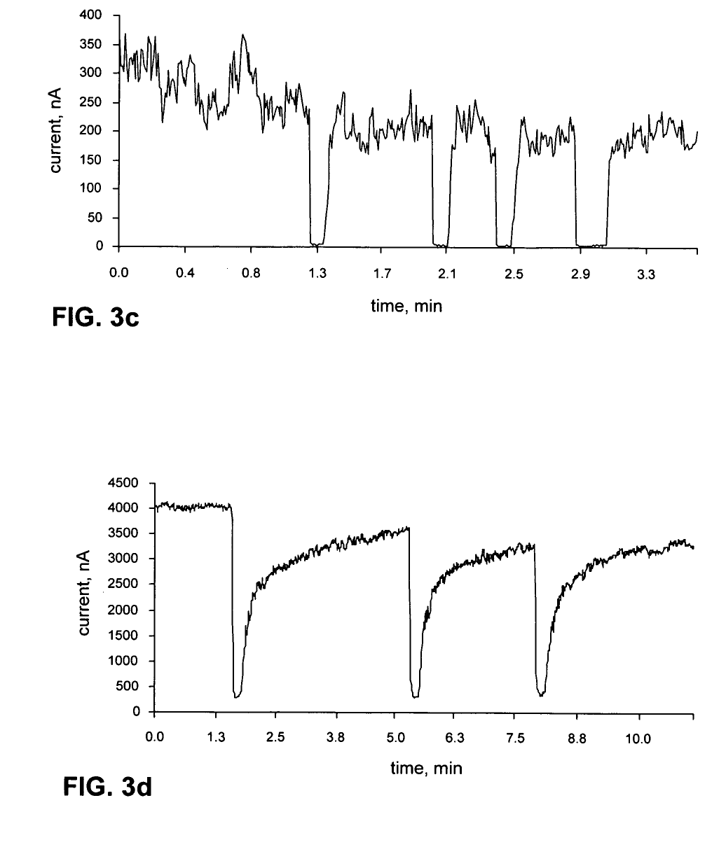

FIGS. 3A-D illustrate the effect of ohmic heating when used to regenerate a nanotube sensor. The performance of this sensor was found to deteriorate over several days, so that its recovery time after sensing became extremely long. FIGS. 3A and 3B show the original fast recovery and the degraded slow recovery, respectively. Heating on a hot plate to a high temperature causes the sensor to recover its initial behavior, as illustrated in FIG. 3C. The same result can be achieved by heating the nanotube ohmically, as illustrated in FIG. 3D. The ohmic heating requires only microwatts, which is much less than even the best micromachined hotplate.

It should be understood that the applications of this method are not limited to these two examples. There are many occasions on which it may be desirable to heat a nanotube device, both for sensors and for other applications. Temperatures between room temperature and 600° C. or more are readily achievable.

The palladium (Pd) coated carbon nanotubes are hydrogen sensors with fast response, high selectivity and reversibility under ambient conditions. We have found that the recovery time of the sensor, which is typically 6-7 minutes, can be decreased down to 5 seconds by heating the sensor in air. The sensor exhibits this fast recovery even after being cooled down to room temperature.

Heating of the Pd-coated carbon nanotube sensors as well as other sensors made from nanostructures can be accomplished by ohmic heating as described above as well as conventional macroscopic heating using an adjacent heat source such as a hot plate or micro-hotplate.

Palladium (Pd) coated carbon nanotubes as hydrogen sensors were described (see J Kong, M G Chapline, H Dai; Adv Mater (2001) 13, 1384-1386, which is incorporated herein by reference. The published time for full recovery of the sensor was ˜400 seconds, which is in full agreement with the examples and observations herein (6-7 minutes).

### Compensation for Temperature, Pressure and Other Factors

In certain embodiments, multiple linear regression (MLR) is used to compensate for variation in temperature, humidity or other factors. If needed, a similar approach may be used for pressure compensation also. For example, a calibration procedure may include electrical measurements of the properties of the sensor, such as resistance, capacitance, impedance, and the like or inductance or combinations of these. Polynomial terms may then be determined to account for nonlinearity, temperature and pressure measurements, and interactions.

In one example of temperature compensation, a product of temperature and resistance be used to account for change of sensitivity with temperature:
C=k₀+k₁R+k₂T+k₃RT+ε

where C is gas concentration, R is sensor resistance, T, temperature and ε, regression error. The calibration data are typically generated using the classic full factorial experiment design. The factors may include the analyte gas concentration, temperature, pressure and even relative humidity Collected data may be stored in a relational database, followed by performing MLR on each sensor. The resulting coefficients and goodness-of-fit statistics are also stored in a database. These coefficients can be applied to data from other tests for validation, and/or programmed into the sensor system firmware for operational use. The procedure may be performed with sensors for multiple analyte gases. Sensors, e.g., a plurality of sensors arrayed on a chip or substrate, may be tested simultaneously in groups.

Preferred embodiments of nanosensors having aspects of the invention may be fabricated on substrates by methods which make it convenient to include other electronic components on the same chip or platform. Thus a thermistor or sensor for another environmental factor may be included on the same chip, simplifying electronic compensation.

Preferably, a calibration procedure for sensor systems having aspects of the invention may be optimized by testing initially with a more comprehensive model of predictors, and then streamlining the procedure by eliminating factors or predictors that are demonstrated to be statistcally insignificant, or unnecessary for a particular application.

For alternative sensors optimized for different analytes or applications, but having similar response characteristics, it may be advantageous to perform principal component analysis (PCA) on test data in some studies. This kind of analysis makes it possible to represent multivariate data in fewer dimensions.

### Nanosensor Integration With Micro-Hotplate-Based Thermo-Regulator

As described above, there are a number of advantages to operation of a nanosensor having aspects of the invention at selected values and ranges of temperatures and other relevant parameters: For example, exemplary embodiments having aspects of the invention may employ thermal regulation (heating and/or cooling) for, among other things:
1. Accelerating analyte sensing reaction rates and reduce sensor response time.
2. To adjust sensor sensitivity for a selected range of analyte concentration (dynamic range).
3. Decreasing cross-sensitivity reaction rates.
4. Restoring and/or regenerating sensor material to a reference state.
5. Optimizing binding or receptor reactions, e.g., polynucleotide hybridization, anti-body/antigen binding, enzyme/substrate reactions, and the like.
6. Controlling condensation and/or evaporation in gas-phase sensor systems.
7. To remove temperature variation in applications where temperature compensation is unsatisfactory.
8. Integrating nanosensors with other process steps (e.g., in an integrated microfluidic nanosensor system) such as concentration, purification, PCR amplification, and the like, which have particular operating optima, thermal cycling ranges or other temperature requirements.
9. Sterilization, and/or incubation of microorganisms or cells in integrated systems employing nanosensors.

### Examples of Integrated Nanosensor/Micro-Hotplate Architecture and Fabrication

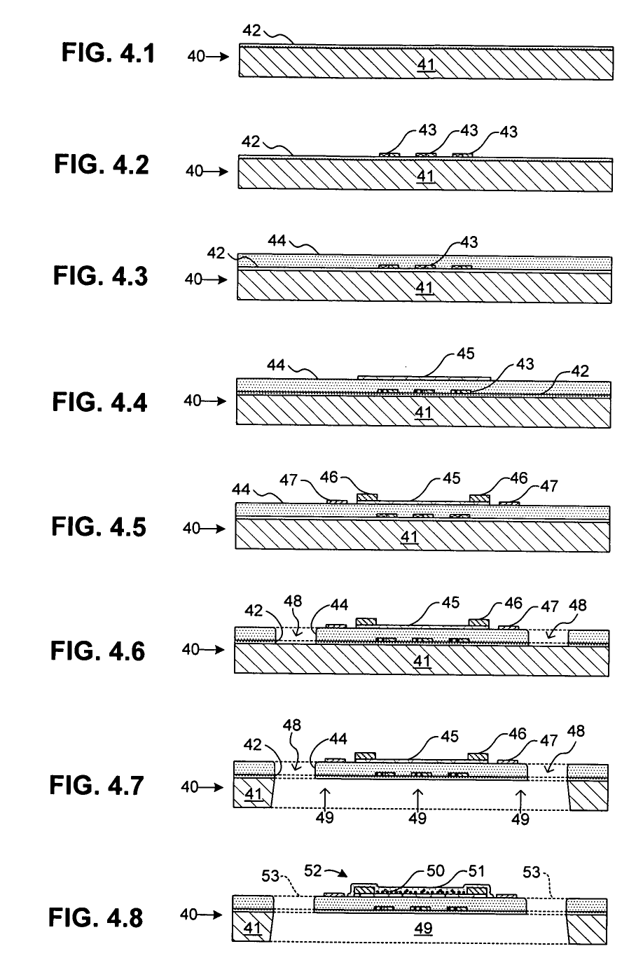

FIGS. 4.1-4.8 illustrate the structure of a sensor device embodiment 40 having aspects of the invention and including an exemplary micro-hotplate. For purposes of clarity in describing the physical relationship of the various elements of device 40, the exemplary process steps shown in FIGS. 4.1-4.8 will be discussed first. The exemplary fabrication processes shown are generally similar to those described in U.S. Pat. No. 6,894,359 entitled “Sensitivity Control For Nanotube Sensors”, which is incorporated by reference.

It should be understood, however, that the process steps shown in the figures are only examples, and that the technology of the electronics industry and related materials science, and in particular the technology of the MEMS, micro-machining and wafer processing industries provide a wide variety of process and materials alternatives which may be employed in making structures such as that of device 50, without undue experimentation and without departing from the spirit of the invention. See, for example, U.S. Pat. No. 5,464,966 entitled “Micro-hotplate devices and methods for their fabrication”; J Kiihamaki et al, “‘Plug-Up+2—A New Concept For Fabricating SOI MEMS Devices”, Microsystem Technologies (2004) 10-5 pp 346-350; R He et al, “Post-Deposition Porous Etching Of Polysilicon: Fabrication And Characterization Of Free-Standing Structures”, Proc. 2004 ASME Intern. Mech. Eng. Congress and Expo., November 2004 Anaheim Calif., (IMECE04-62198); J-A Paik et al, “Micromachining of Mesoporous Oxide Films for Microelectromechanical System Structures”, J. Materials Research (2002) 17-8 pp. 2121-29; R He et al, “Porous Polysilicon Shell Formed by Electrochemical Etching for On-Chip Vacuum Encapsulation”, Solid-State Sensor, Actuator and Microsystems Workshop (HH'04), Hilton Head Island, S.C., June 2004, pp.332-5; D-J Yao et al, “MEMS Thermoelectric Microcooler”, Proc. 20th International Conference on Thermoelectrics, Beijing, China, June 2001, pp. 401-404; and D J Young et al, “A Micromachined Variable Capacitor for Monolithic Low-Noise VCOs”, Technical Digest, IEEE Solid-State Sensor and Actuator Workshop, Hilton Head Island S.C., June 1996, pp. 86-89; each of which patent and publication is incorporated by reference herein.

FIGS. 4.1-4.8 show cross-sections of sensor device 40 at successive stages of the exemplary fabrication procedure which may be employed. The device shown is configured to include a transconductance nanosensor of the general type described in US Published Patent Application No. 2005-0129,573 entitled “Carbon Dioxide Nanoelectronic Sensor” (which is incorporated by reference), but may include one or more sensors selected from a range of architectures and measurement configurations, such as a nanoelectronic FET sensor, a nanoelectronic capacitance sensor, and the like. See for example, U.S. patent application Ser. No. 11/111,121 “Remotely communicating, battery-powered nanostructure sensor devices”; and U.S. Patent Application No. 60/669,126 entitled “Systems Having Integrated Cell Membranes And Nanoelectronics Devices, And Nano-Capacitive Biomolecule Sensors”; each of which is incorporated by reference herein.

FIG. 4.1 shows the initial substrate 41, in this example including a surface coating 42. In is example, the substrate is a monocrystalline silicon wafer, and the surface coat is a thin dielectric layer of Si3N4 which electrically isolates substrate 41.

FIG. 4.2 shows the deposition of one or more temperature-sensing devices 43 and associated conductor leads upon the top dielectric layer 42 of substrate 41. This may include a semiconductor thermistor, Pt thermistor, or other suitable devices. Typically, a thermistor includes a resistor device calibrated to provide a sensitive measurement of temperature. The elements of the thermistor and its conductors, shown schematically, may be deposited on the substrate by known methods. Note that the thermistor may also serve as a gate electrode or counter electrode.

FIG. 4.3 shows the deposition of a covering layer 44, (e.g. SiO₂, Al₂O₃, or Si₃N₄) which isolates the thermistors from the overlying device elements.

FIG. 4.4 shows the deposition of a nanostructure layer 45 on the surface of covering layer 44. In preferred embodiments having aspects of the invention, a interconnected network of single wall carbon nanotubes (SWNTs) is included as the nanostructure layer 45.

For example, a nano-smooth layer of SiO₂ provides a favorable surface on which to grow a network of SWNTs by CVD methods, such as are described in U.S. patent application Ser. No. 10/177,929 entitled “Dispersed Growth Of Nanotubes On A Substrate” (see published counterpart WO.04-040,671) which is incorporated by reference. PECVD methods may be employed in a reduced-temperature CVD process, which may be advantageous in certain applications to protect temperature sensitive elements; see Y Li et al, “Preferential Growth of Semiconducting Single-Walled Carbon Nanotubes by a Plasma Enhanced CVD Method”, NANOLETTERS (2004) V.4-N.2 pp 317-321, which is incorporated by reference.

Alternatively, solution deposition, spin-casting, vacuum-filtration deposition or ink-jet type deposition methods, and the like, may be employed produce a suitable nanostructured layer, e.g. of SWNTs upon substrate 41. See for example, U.S. patent application Ser. No. 10/846,072 filed May 14, 2004 entitled “Flexible Nanotube Transistors”; and L. Hu et al., “Percolation in Transparent and Conducting Carbon Nanotube Networks”, NANOLETTERS (2004), V.4-N.12, pp 2513-17, each of which application and publication is incorporated herein by reference.

FIG. 4.5 shows the deposition of one or more conductors or contacts 46 upon the nanostructured layer 45 to act as electrical contacts for measurement of electrical properties. In addition, one or more heater elements 47 may be deposited adjacent the sensor structure. For example, by suitable selection of dimensions, heater elements and sensor contacts may be deposited using the same metal materials. Note that alternative configurations may be employed without departing from the spirit of the invention, such as depositing the contacts 46 directly on the covering layer 44, prior to deposition of nanostructured layer 45. Likewise, heater elements 47 may be depositing the in the same layer as the thermistors 43 on surface layer 42, and so be buried beneath cover layer 44.

FIG. 4.6 shows the opening of annular ports 48 in the surface layer 42 and cover layer 44, e.g. by etching of the SiO₂ and Si₃N₄ layers though a photoresist mask, in preparation of one or more thermal isolation “bridges” 53. Buffered oxide etch (BOE), can be used as a wet etch agent for silicon oxides, as well as other processes known in the semiconductor arts.

FIG. 4.6 shows the selective removal of substrate material, e.g., by deep reactive ion etching (DRIE) through a mask from the substrate underside to produce isolation cavity 49. A suitable apparatus for removal of base monocystalline silicon without damaging the layer 42 and 44 is the Centura® Deep Silicon Etch DPS-DT. The removal of the substrate portions leaves the bridge portions 53 (comprising portions of the layers 42 and 44) and the suspended platform 52 in isolation from the remaining substrate material 41 around the perimeter. The heat transfer by conductance from panel 52 to substrate 41 through the remaining structural contact of the bridges 53 is minimal.

Low power use in turn reduces heat dissipation requirements, and makes the sensor device particularly suitable for long-life portable or distributed applications with having limited energy sources (batteries, micro-fuel cells, photocells, or alternative energy resources of low-power output or low total energy storage). A an embodiment of a sensor device integrated with a suspended microhotplate typically has a power consumption of roughly 1 mW per 40° F. For example, and having a working temperature of about 140° F., would induce an average power consumption of about 2 to 3 mW for an average ambient temperature between 20 to 60° F. See, for example, C. Tsamis et al, “Fabrication of suspended porous silicon micro-hotplates for thermal sensor applications”, Physica Status Solidi (a), Vol. 197 (2), p. 539-543 (2003); and A. Tserepi et al, “Fabrication of suspended thermally insulating membranes using front-side micromachining of the Si substrate: characterization of the etching process”, J. of Micromech. and Microeng, Vol. 13, p. 323-329 (2003); and US Published Application 2004-0195,096, “Method For The Fabrication Of Suspended Porous Silicon Microstructures”; each of which applications and publications are incorporated by reference.

### Examples of Suspended Heated Nanotube Transistor Device

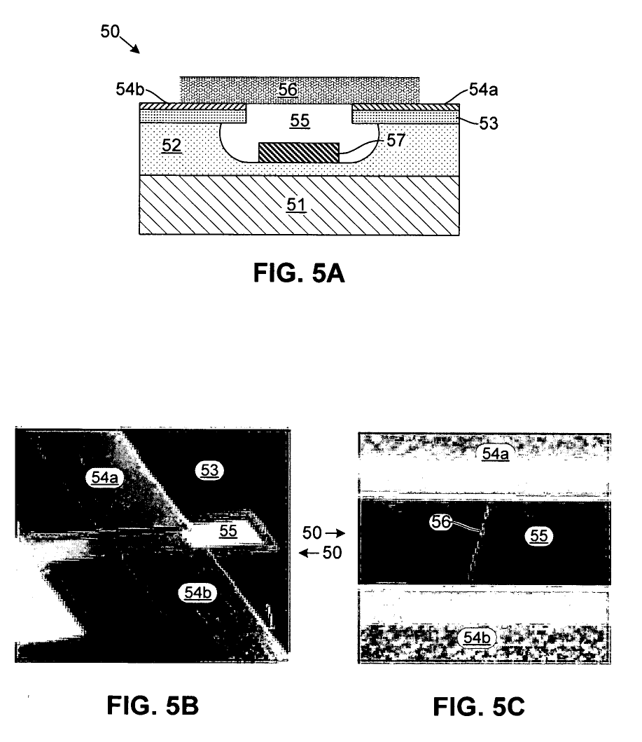

FIG. 5A shows an alternative exemplary nanostructure sensing device according to the invention having a suspended carbon nanotube and a local gate electrode. Exemplary device 50 is similar in a number of respects to the device shown in FIG. 1B, and the description related to that device is to be noted.

FIGS. 5B and 5C are SEM micrograph images of an embodiment generally similar to that diagramed in FIG. 5A, FIG. 5B being an oblique perspective view, and FIG. 5C being a more greatly magnified plan view.

Device 50 comprises a substrate 51, such as a silicon wafer, coated with a dielectric layer 52, including for example SiO2. An etch-resistant layer 53, including for example Si3N4, overlays layer 52, and is in turn overlain by contact layer 54, which includes, for example, Platinum. Note that contact layer 54 and layer 53 are subdivided by a slot 55, the slot serving to separate contact layer 54 into a pair of contacts 54a and 54b. The width of slot 55 may be from a fraction of a micron (e.g. 0.5 microns), up to several microns (e.g. 10 microns). A nanostructure 56 (e.g., one or more semiconducting carbon nanotubes) spans between contacts 54a and 54b.

Slot 55 may be deepened by etching processes (see description relating to FIG. 1B and FIG. 4.1-4.8) so as to effectively isolate nanostructure 56 from the substate layers 52 and 53. The etching is preferably done prior to positioning of nanostructure 56. A local gate electrode 57 may be deposited within slot 55 in proximity to nanostructure 56, so as to capacitively influence the properties of nanostructure 56, in the manner of a field effect transistor.

Current between contacts 54a and 54b may be employed to thermally regulate nanostructure 56. It has been demonstrated previously that freely suspended single-walled carbon nanotubes exhibit reduced current carrying ability compared to those lying on substrates. Theoretical analysis reveals significant self-heating effects including electron scattering by hot non-equilibrium optical phonons. For suspended SWNTs, heat dissipation only occurs along the tube length to the contacts. At a given bias V the lattice temperature of the suspended SWNT can be determined by the power dissipation and the thermal conductivity of the tube.

Process steps may include:
a. Building the trench area by a lithography step and followed by dry etching of Si3N4 and wet etching of SiO2.
b. Defining source/drain and local gate by lithography step and followed by metal deposition. W/Pt can be used as electrode material to provide thermal budget required for CVD process.
c. Patterning and depositing catalyst island near the edge of the trench, followed by CVD process (see parent application, now U.S. Pat. No. 6,894,359, which is incorporated by reference).
d. In an alternative, nanostructure 56 may be deposited from solution. See for example, the methods described in U.S. patent application Ser. No. 10/846,072, filed May 14, 2004 entitled “Flexible Nanotube Transistors”, which is incorporated by reference. Alternative methods may be employed to deposit the solution or suspension of nanostructures such as SWNTs, in the manner described in U.S. patent application Ser. No. 11/274,747 filed Nov. 14, 2005 entitiled “Nanoelectronic Glucose Sensors”, which application is incorporated by reference.

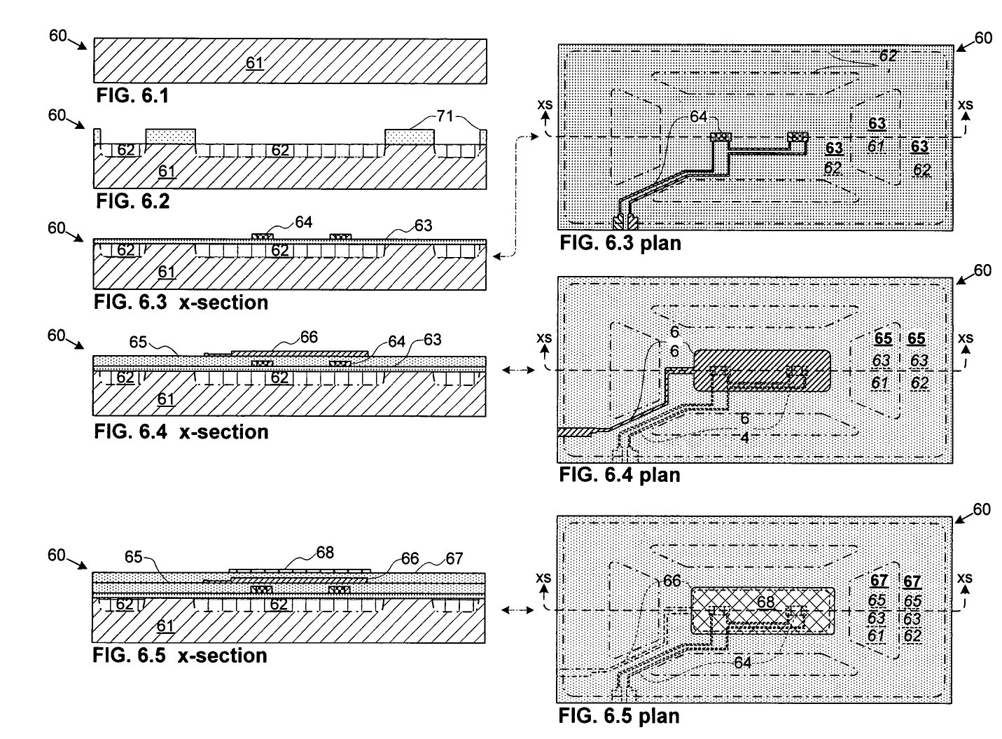

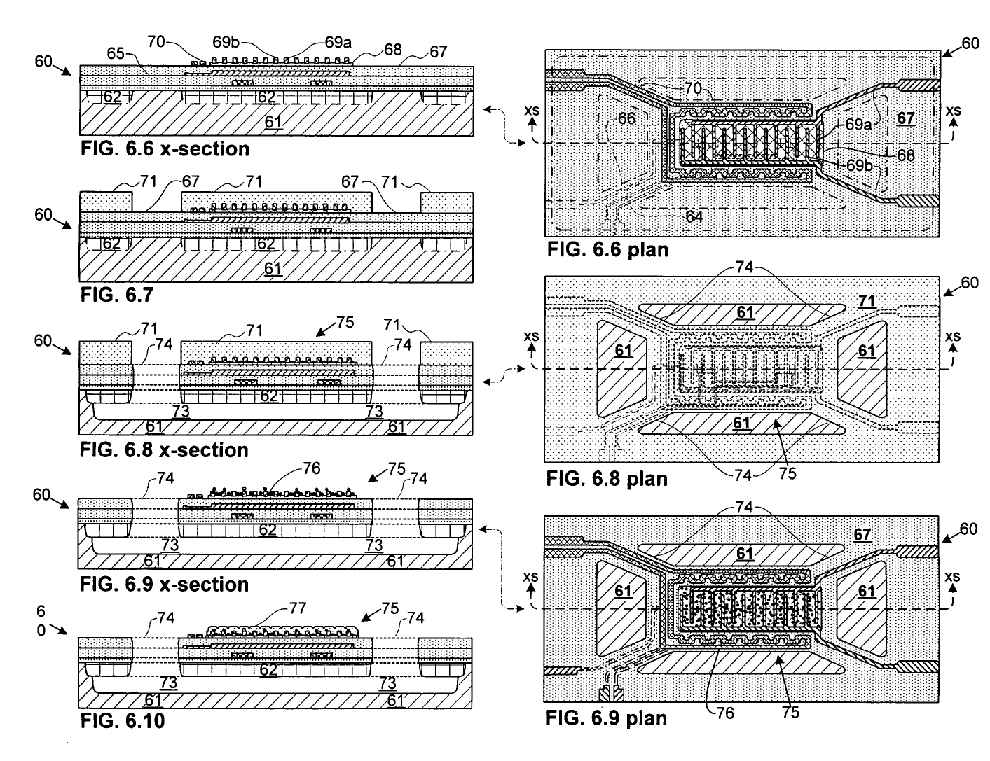

FIGS. 6.1-6.10 shows an alternative sequence of exemplary steps which may be employed for making the sensor device embodiment 60 having aspects of the invention. The fabrication processes shown make use of the differential in etch rate of porous silicon versus a crystalline silicon substrate, of the general nature of the processes described in US Published Application 2004-0195,096; and C. Tsamis et al, Physica Status Solidi (a), Vol. 197 (2), p. 539-543 (2003); as well as G. Kaltsas et al, “Front-side bulk silicon micromachining using porous silicon technology”, Sensors and Actuators: A, 65, (1998) p.175-179; and G. Kaltsas et al, “Bulk silicon micromachining using porous silicon sacrificial layers”, Microelec. Eng. 35, (1997), pp. 397-400, each of which are incorporated by reference.

FIG. 6.1 is a cross section showing the initial substrate 61 of device 60, in this example a doped monocrystalline silicon wafer.

FIG. 6.2 is a cross section showing the a pattern region of porous silicon 62 formed within substrate 61 of device 60, using suitable mask 71 (e.g., a silicon dioxide layer and a polysilicon layer) to define the region 62. For example, this may be done by anodization carried out in an electrolytic cell (e.g., with anodization current ranges between 10 to 80 mA/cm², while the anodization time ranges between 1 to 10 min), and may be followed by thermal treatment, e.g., (as per Tsamis et al, supra). The region 62 is preferably defined 3-dimensionally in lateral extent and thickness, so as to leave selected thickness of un-altered base portion of crystalline silicon substrate 61.

Note that at the right side of the plan views of FIGS. 6.3, 6.4 and 6.5 plan, the reference number for the surface material is shown bold and solid underscore, the reference number for each the underlying layer of material is shown in italics and dashed underscore, in order of depth of the respective layer. Thus, for example, in FIG. 6.3 plan, the region 62 of covered porous silicon is delineated by phantom lines 62′, which marks the subdivisions between regions in which the material underlying the insulating layer 63 is porous silicon 62 or crystalline silicon 61 respectively.

FIGS. 6.3 x-section and 6.3 plan are a cross section and a plan view respectively of the device 60, showing the substrate 61 of device 60, following a deposition of an insulating layer 63, e.g. Si₃N₄, or the like. One or more temperature sensing devices and suitable electrical leads, e.g., thermistors 64, are deposited upon the insulating layer 63.

The leads of thermistors 64 preferably extend to adjacent edges of device 60 to permit convenient conventional connections to suitable operating circuitry (not shown), such as by vias, pads and the like. Note that the path of the leads on layer 63 anticipates the formation of “bridges” (74 in FIGS. 6.8-6.1) by being deposited upon regions underlain by porous silicon 62.

It should be understood that while a single device 60 is shown in FIGS. 6.1-6.10 for purposes of clarity, the device 60 may be one of a plurality of devices fabricated simultaneously much larger substrate or wafer, the substrate and associated circuitry typically being subdivided into a plurality distinct “chips”. Each such “chip” may include one or more additional sensors, such as an array of sensors (and optionally integrated circuitry or other components) fabricated on the same chip adjacent to device 60.

FIGS. 6.4 x-section and 6.4 plan are a cross section and a plan view respectively of the device 60, showing the substrate 61 of device 60, following a deposition of a first covering layer 65 e.g. SiO2, or the like. An optional gate and/or counter electrode 66 and suitable electrical leads (e.g. metals such as Pt, Ti and the like) may then be deposited upon the first cover layer 65, the leads preferably extending to adjacent edges of device 60.

FIGS. 6.5 x-section and 6.5 plan are a cross section and a plan view respectively of the device 60, showing the substrate 61 of device 60, following a deposition of a second covering layer 67 e.g. SiO2, or the like. A conductive nanostructure element 68, e.g., comprising an interconnected network of single walled carbon nanotubes (SWNTs), is deposited upon the second cover layer 67 (see discussion above with respect to FIG. 4.4), the element 68 shown in this example to be approximately co-extensive with the buried gate or counter electrode 66.

FIGS. 6.6 x-section and 6.6 plan are a cross section and a plan view respectively of the device 60, showing the substrate 61 of device 60, following a deposition of the elements of one or more electrical contacts 69 and one or more heaters 70. These may comprise metals or other conducting materials, and may be deposited in one or more layers, e.g. a base adhesion layer and a overlying conduction layer. Optionally, the heater and electrical contacts may comprise the same composition(s) to reduce process steps and costs.

In the example shown, the contacts 69 comprise a dual set of interdigitated spaced-apart contacts 69a and 69b, and their respective leads. The interdigitated contacts 69a,b are preferably approximately evenly spaced co-extensively with SWNT network 68. Note that although the contacts are shown above the network 68, there are alternative suitable configurations, such as depositing contacts 69 beneath the network 68.

Likewise, the heater elements 70 are shown disposed to the sides of contacts 69, spaced closely enough to provide rapid and even heating of the network region 68. Alternative configurations are possible, e.g. depositing heater elements beneath the cover layer 67, and the like.

FIG. 6.7 is a cross section showing the device 60, in which the layer 67 and associated contacts 69, heater 70, nanostructure element 68 have been covered with a patterned mask (e.g., photoresist material), leaving exposed portions of layer 67, shaped to define the bridge and cavity structure (see FIG. 6.8).

FIGS. 6.8 x-section and 6.8 plan are a cross section and a plan view respectively of the device 60, showing the substrate 61 of device 60, following removal of the exposed portions of both insulating and cover layers 63, 65 and 67, together with the removal of the portions of the crystalline silicon substrate 61, so as to define bridges 74 and isolation cavity 73, thereby defining the suspended sensor platform or membrane 75. The layers 63, 65 and 67 may be removed by wet etching, dry etching or a combination.

The removal of portions of region 61 may be by anisotropic and/or isotropic dry etching processes (see the above incorporated references US 2004-0195,096; and Tsamis et al). For example, by plasma generation using an F-rich gas as sulfur hexafluoride (e.g., with a flow of between 100-300 sccm and a processing pressure between 1 and 10 Pa), using a high frequency supply (e.g., about 13.56 MHz at outputs between 500 W and 2000 W). At the same time, a low substrate voltage (e.g., about 30 and 60 V) for ion acceleration is supplied to the substrate electrode.

Such techniques can show an etch rate differential between the porous silicon 62 and the base silicon 61 on the order of 1:100. A strongly anisotropic etch rate may be achieved which can undercut and release platform 75 by comparatively rapid lateral etching, while maintaining the substrate floor region, so as to form bridged isolation cavity 73.

FIGS. 6.9 x-section and 6.9 plan are a cross section and a plan view respectively, showing the functionalization of the sensor device 60. A number of functionalization methods or strategies may be employed without departing from the spirit of the invention.

Functionalization may be accomplished by treating the nanostructure element 68 at one of several alternative stages of device fabrication. As shown, the functionaliztion step follows the definition of the bridges 74 and cavity 73, but it may be accomplished either earlier or later. Functionalization may be accomplished prior to beginning device fabrication, such as by treating the nanostructure composition prior to formation of nanostructure element 68 (e.g. pre-fuctionalized SWNTs). Alternatively, for certain applications and compositions, the nanostructure element 68 may need additional functionalization.

A number of alternative strategies and composition for nanosensor functionalization may be employed, depending on the analyte(s) of interest, the sensitivity and specificity required, and environmental and service life requirements, among other things. Among many examples, recognition materials may be deposited or formed upon various device elements (e.g., nanostructures, contacts, substrates and coating layers), so as to induce a measurable change of one of more device properties in response to an analyte of interest. Similarly, chemical or structural changes may be induced in the nanostructure element 68 composition, such as by inducing point defects or gaps in a molecular lattice structure, by substituting groups in a nanostructure lattice, by incorporating groups in internal nanostructure voids (e.g., within a carbon nanotube core), by creating Schottky barriers at metal/semiconductor junctions, and the like. Molecular transducers may be attached to device elements, configured to selectively interact with analytes to produce a measurable change in device properties, for example including probe biomolecules (e.g., DNA, enzymes, antibodies, etc.), ligand groups, connector groups, enhancer groups, and the like.

FIGS. 6.9 show a representative particulate functionalization or recognition layer 76, which is deposited on nanostructure element 68 and electrodes 69 approximately coextensively with nanostructure element 68, so as to adhere to the device surface.

FIG. 6.10 is a cross section showing the device 60, in which a layer 77 has been formed covering portions of the device surface. Layer 77 by include an encapsulation layer for environmental protection, a passivation layer covering certain structures (e.g., contact regions between nanostructure element 68 and contacts 69), a selectively permeable layer permitting passage of an analyte of interest, and inhibition layer at least partially excluding selected species, and the like. A shown, layer 77 is deposited on nanostructure element 68 and electrodes 69 covering recognition material 76, approximately coextensively with nanostructure element 68, although it may cover additional or fewer portions of device 60 (For example, configured to cover heaters 70 and/or configured to leave pores open to nanostructure element 68). Additional layers or coating (not shown) may be included.

### Thermo-Regulation

Integrated nanosensor/micro-hotplate devices having aspects of the invention are highly suitable to applications requiring precise temperature regulation. Typically, when an integrated nanosensor/micro-hotplate device embodiment is to be operated at a temperature substantially above ambient, a stable temperature may be maintained by natural heat out-flow (e.g., by heat conduction through device elements, by radiation, and by conduction and convection through surrounding air or fluids) balanced by controlled heat production (e.g., the sum of intrinsic device heat dissipation and the controlled hotplate heat production). For example, given a suspended device platform or membrane temperature target point in the range of about 120-160° F., and given low intrinsic device power consumption/heat generation, the natural heat transport by ambient air conduction and natural convection is typically adequate to permit thermoregulation.

In certain applications, operating temperature may need to be cycled through a substantial range of temperatures and may require rapid rates of temperature change (e.g., sensors integrated with PCR systems and the like). In other applications, wide variation in environment ambient temperature may complicate thermo-regulation. To address these and other requirements, in alternative embodiments having aspects of the invention, further cooling capacity may be included, such as forced convection and heat sinks (such as is commercially used for cooling high-speed processor chips), liquid cooling loops, heat pipes and the like. In additional alternative embodiments, refrigeration mechanisms may be included and/or integrated in sensor devices having aspects of the invention without departing from the spirit of the invention, such as thermoelectric or Peltier coolers, thermionic coolers utilizing electron thermal energy dissipation, and the like. See for example, D-J Yao et al, “MEMS Thermoelectric Microcooler”, Proc. 20th International Conference on Thermoelectrics, Beijing, China, June 2001, pp. 401-404; and US Published Applications 2003-0020,072 and 2003-0020,132, each of which is incorporated by reference.

Having thus described preferred embodiments of the nanotube device, it should be apparent to those skilled in the art that certain advantages of the within system have been achieved. It should also be appreciated that various modifications, adaptations, and alternative embodiments thereof may be made within the scope and spirit of the present invention. For example, particular configuration has been illustrated, but it should be apparent that the inventive concepts described above would be applicable to other configurations, such as those that employ a plurality of nanotubes. The invention is further defined by the following claims.

1. A nanoelectronic sensing device having a sensitivity for at least one analyte of interest, comprising:
a substrate,
a nanostructure element disposed adjacent the substrate; and
at least one conductive element electrically connected to the nanostructure element;
wherein the device is configured to heat at least a portion of the sensor structure including the nanostructure element.

2. The sensing device of claim 1, further comprising at least a heating element disposed adjacent the nanostructure element and providing heat to the nanostructure element.

3. The sensing device of claim 1, wherein the substrate is configured to form at least one cavity adjacent the nanostructure element and providing thermal isolation for the nanostructure element from at least a portion of the substrate.

4. Methods, devices, assemblies, subassemblies, kits, and software products substantially in the spirit of the inventive embodiments described herein.

5. A transistor device; comprising:
a microhotplate including:
a substrate having a bulk portion and a suspended portion, the suspended portion connected to the bulk portion so as to be substantially thermally isolated from the bulk portion;
at least one heating element disposed adjacent the suspended portion;
a transistor including:
a semiconducting channel comprising one or more nanostructure elements, the channel disposed adjacent the suspended portion and configured so as to be heated by the heating element;
at least a pair of contacts electrically communicating with the channel;
at least one gate electrode configured to electrically influence the channel.

6. The transistor device of claim 5, wherein the one or more nanostructure elements comprise one or more carbon nanotubes.

7. The transistor device of claim 5, further comprising a temperature sensor.

8. The transistor device of claim 7, further comprising a controller configured to:
control the heat produced by the heating element;
receive a temperature signal from the temperature sensor; and
regulate the heat produced by the heating element to maintain a target temperature of the channel.

9. The transistor device of claim 5, wherein the transistor device is configured as a sensor having a sensitivity to an analyte of interest.

10. A sensor device for sensing at least an analyte of interest; comprising:
a microhotplate including:
a substrate having a bulk portion and a suspended portion, the suspended portion connected to the bulk portion so as to be substantially thermally isolated from the bulk portion;
at least one heating element disposed adjacent the suspended portion;
a nanosensor including:
at least one nanostructure element disposed adjacent the suspended portion and configured so as to be heated by the heating element;
one or more contacts configured to electrically communicate with the nanostructure element;
a recognition material disposed in operative association with the nanostructure element and configured to interact with the analyte of interest.

11. The sensor device of claim 10, wherein the at least one nanostructure element comprises at least one carbon nanotube.

12. A sensor device for sensing at least an analyte of interest, comprising:
a substrate,
at least one elongate nanostructure element having a conductivity and disposed adjacent the substrate, wherein at least a portion of the elongate nanostructure element is space apart from the substrate;
one or more conductive elements electrically connected to the nanostructure element and configured to permit an electrical current to be conducted along the elongate nanostructure element so as to dissipate energy as heat in at least a portion of the elongate nanostructure element; and
a recognition material disposed in operative association with the nanostructure element and configured to interact with the analyte of interest.

13. The sensor device of claim 12, further comprising a gate electrode disposed to electrically influence the elongate nanostructure element;
wherein the substrate has a top surface and a slot in the top surface;
wherein the conductive elements comprise a pair of contacts adjacent the top surface on opposing sides of the slot; and
wherein the elongate nanostructure element is arranged to span the slot and to be in electrical communication with each of the pair of contacts.

14. The sensor device of claim 13, wherein the slot has a bottom surface disposed spaced-apart from the elongate nanostructure element, and wherein the gate electrode is disposed adjacent the bottom surface.

15. The sensor device of claim 12, wherein the elongate nanostructure element comprises one or more carbon nanotubes.

16. A transistor device, comprising:
a substrate;
at least one elongate nanostructure element having a conductivity and disposed adjacent the substrate, wherein at least a portion of the elongate nanostructure element is space apart from the substrate;
one or more conductive elements electrically connected to the nanostructure element and configured to permit an electrical current to be conducted along the elongate nanostructure element so as to dissipate energy as heat in at least a portion of the elongate nanostructure element; and
a gate electrode disposed to electrically influence the elongate nanostructure element.

17. The transistor device of claim 16:
wherein the substrate has a top surface and a slot in the top surface;
wherein the conductive elements comprise a pair of contacts adjacent the top surface on opposing sides of the slot; and
wherein the elongate nanostructure element is arranged to span the slot and to be in electrical communication with each of the pair of contacts.

18. The transistor device of claim 16, wherein the slot has a bottom surface disposed spaced-apart from the elongate nanostructure element, and wherein the gate electrode is disposed adjacent the bottom surface.

19. The sensor device of claim 16, wherein the elongate nanostructure element comprises one or more carbon nanotubes.
